(19) United States
(12) Patent Application Publication
(10) Pub. No.: US 2026/0282916 A1
(43) Pub. Date: Sep. 17, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Makoto UTSUMI, Matsumoto-city (JP)

(73) Assignee: FUJI ELECTRIC CO., LTD., Kawasaki-shi (JP)

(21) Appl. No.: 19/460,608

(22) Filed: Jan. 27, 2026

(30) Foreign Application Priority Data
Mar. 14, 2025 (JP) 2025-041915

(51) Int. Cl. H10W 42/00; H10D 62/10

(52) U.S. Cl. CPC H10W 42/00; H10D 62/106

(57) ABSTRACT

A semiconductor device, including: a semiconductor substrate having an active region and a termination region surrounding a periphery of the active region in a plan view; a first semiconductor region provided on a surface of the semiconductor substrate; a second semiconductor region provided in the first semiconductor region at a surface thereof, in an end portion of the termination region; an insulating film provided at the surface of the first semiconductor region; and a polyimide film selectively provided at a surface of the insulating film. The insulating film covers the first and second semiconductor regions. The polyimide film covers the surface of the insulating film. The semiconductor device further has, in the end portion of the termination region, an uneven portion through which the first semiconductor region and the second semiconductor region are exposed.

### CROSS REFERENCE TO RELATED APPLICATIONS

This application is based upon and claims the benefit of priority of the prior Japanese Patent Application No. 2025-041915, filed on Mar. 14, 2025, the entire contents of which are incorporated herein by reference.

### BACKGROUND OF THE INVENTION

### 1. Field of the Invention

Embodiments of the disclosure relate to a semiconductor device and method of manufacturing a semiconductor device.

### 2. Description of the Related Art

Conventionally, to improve moisture resistance and power cycle capacity, at a portion of an oxide film covered by an organic insulating film, a semiconductor device is known that has at least one of a downwardly recessed groove and an upwardly protruding ridge, the groove having a portion where the width decreases toward the top, and the ridge having a portion where the width is greater toward the top (for example, refer to Japanese Laid-Open Patent Publication No. 2023-172987).

### SUMMARY OF THE INVENTION

According to an embodiment of the present disclosure, a semiconductor device, includes: a semiconductor substrate of a conductivity type, the semiconductor substrate having an active region and a termination region surrounding a periphery of the active region in a plan view; a first semiconductor region of the conductivity type, provided on a surface of the semiconductor substrate; a second semiconductor region of the conductivity type, provided in the first semiconductor region at a surface thereof, in an end portion of the termination region; an insulating film provided at the surface of the first semiconductor region; and a polyimide film selectively provided at a surface of the insulating film. The insulating film covers the surface of the first semiconductor region and a surface of the second semiconductor region. The polyimide film covers the surface of the insulating film and reaches a portion of the end portion of the termination region. The semiconductor device further has, in the end portion of the termination region, an uneven portion through which the first semiconductor region and the second semiconductor region are exposed.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment, along cutting line X-X′ depicted in FIG. 3.

FIG. 2 is a cross-sectional view depicting the structure of the silicon carbide semiconductor device according to the first embodiment, along cutting line Y-Y′ depicted in FIG. 3.

FIG. 3 is a top view of the structure of the silicon carbide semiconductor device according to the first embodiment.

FIG. 4 is a flowchart of the method of manufacturing the silicon carbide semiconductor device according to the first embodiment.

FIG. 5 is a cross-sectional view depicting a structure of a silicon carbide semiconductor device according to a second embodiment, along cutting line X-X′ depicted in FIG. 6.

FIG. 6 is a top view of the structure of the silicon carbide semiconductor device according to the second embodiment.

FIG. 7 is a cross-sectional view depicting a structure of a silicon carbide semiconductor device according to a third embodiment, along cutting line X-X′ depicted in FIG. 8.

FIG. 8 is a top view of the structure of the silicon carbide semiconductor device according to the third embodiment.

FIG. 9 is a cross-sectional view depicting a structure of a silicon carbide semiconductor device according to a fourth embodiment, along cutting line X-X′ depicted in FIG. 10.

FIG. 10 is a top view of the structure of the silicon carbide semiconductor device according to the fourth embodiment.

FIG. 11 is a flowchart of a method of manufacturing the silicon carbide semiconductor device according to the fourth embodiment.

FIG. 12 is a cross-sectional view depicting a structure of a silicon carbide semiconductor device of a comparison example.

FIG. 13 is a cross-sectional view depicting a structure having grooves at an end of the silicon carbide semiconductor device of the comparison example.

### DETAILED DESCRIPTION OF THE INVENTION

First, problems associated with the conventional techniques are discussed. In the conventional semiconductor device, a problem arises in that, when a thermal shock test was performed, mold resin began to peel from an outermost periphery of the chip.

An outline of an embodiment of the present disclosure is described. A semiconductor device according to the present disclosure has the following features. The semiconductor device includes: a semiconductor substrate of a predetermined conductivity type, having an active region and a termination region surrounding a periphery of the active region in a plan view; a first semiconductor region of the predetermined conductivity type, provided at a surface of the semiconductor substrate in the termination region; a second semiconductor region of the predetermined conductivity type, provided at a surface of the first semiconductor region, at an end of the termination region; an insulating film provided at the surface of the first semiconductor region in the termination region; and a polyimide film selectively provided at a surface of the insulating film in the termination region. The insulating film covers the surface of the first semiconductor region and a surface of the second semiconductor region to the end of the termination region. The polyimide film covers the surface of the insulating film and reaches a portion of the end portion of the termination region. Unevenness exposing the first semiconductor region and the second semiconductor region is provided at the end of the termination region.

According to the disclosure above, unevenness at the surface of the insulating film is provided from the second semiconductor region (the n⁺-type region) to a region where the polyimide film is formed, exposing the SiC and forming an uneven pattern. As a result, an anchoring effect of mold resin is obtained by fine unevenness of a SiC surface formed by etching and an uneven pattern of the interlayer insulating film. Thus, the strength of adhesion between the chip and the mold resin is improved, peeling of the mold resin may be prevented, and reliability with respect to thermal shock may be improved.

Further, in the semiconductor device according to the present disclosure, in the disclosure above, the unevenness is a groove that reaches the first semiconductor region and the second semiconductor region formed at the surface of the insulating film.

Further, in the semiconductor device according to the present disclosure, in the disclosure above, the unevenness is provided from the second semiconductor region to a region where the polyimide film is formed.

Further, in the semiconductor device according to the present disclosure, in the disclosure above, the unevenness is provided on an outer side of a region where the polyimide film is formed.

Further, in the semiconductor device according to the present disclosure, in the disclosure above, the insulating film covers the surface of the first semiconductor region and the surface of the second semiconductor region and reaches a portion of the end portion of the termination region, and the unevenness is a groove provided at the surface of the first semiconductor region and the surface of the second semiconductor region.

Further, in the semiconductor device according to the present disclosure, in the disclosure above, surface roughness Rmax of the first semiconductor region and the second semiconductor region provided with the unevenness is in a range of 3 nm to 10 nm.

Further, in the semiconductor device according to the present disclosure, in the disclosure above, the unevenness includes a recess and a protrusion, a width of the protrusion being wider than a width of the recess.

A method of manufacturing a semiconductor device has the following features. In the method of manufacturing a semiconductor device having an active region and a termination region surrounding a periphery of the active region in a plan view, a semiconductor substrate of a predetermined conductivity type is prepared and first semiconductor region of the predetermined conductivity type is formed at a surface of the semiconductor substrate as a first process. A second semiconductor region of the predetermined conductivity type is formed at a surface of the first semiconductor region, at an end of the termination region as a second process. An insulating film is formed at the surface of the first semiconductor region to the end of the termination region as a third process, the insulating film covering the surface of the first semiconductor region and a surface of the second semiconductor region. Unevenness exposing the first semiconductor region and the second semiconductor region is formed at the end of the termination region as a fourth process. A polyimide film is formed at a surface of the insulating film as a fifth process, the polyimide film covering the surface of the insulating film and reaches a portion of the end portion of the termination region, the polyimide film exposing at least the unevenness.

A method of manufacturing a semiconductor device has the following features. In the method of manufacturing a semiconductor device having an active region and a termination region surrounding a periphery of the active region in a plan view, a semiconductor substrate of a predetermined conductivity type is prepared and first semiconductor region of the predetermined conductivity type is formed at a surface of the semiconductor substrate as a first process. A first semiconductor region of the predetermined conductivity type is formed at a surface of the semiconductor substrate as a second process. A second semiconductor region of the predetermined conductivity type is formed at a surface of the first semiconductor region, at an end of the termination region as a third process. An insulating film is formed at the surface of the first semiconductor region as a third process, the insulating film covering the surface of the first semiconductor region and a surface of the second semiconductor region and reaches a portion of the end portion of the termination region. Unevenness having a groove is formed at the surface of the first semiconductor region and the surface of the second semiconductor region, at the end of the termination region as a fourth process. A polyimide film is formed at a surface of the insulating film as a fifth process, the polyimide film covering the surface of the insulating film and reaches a portion of the end portion of the termination region, the polyimide film exposing at least the unevenness.

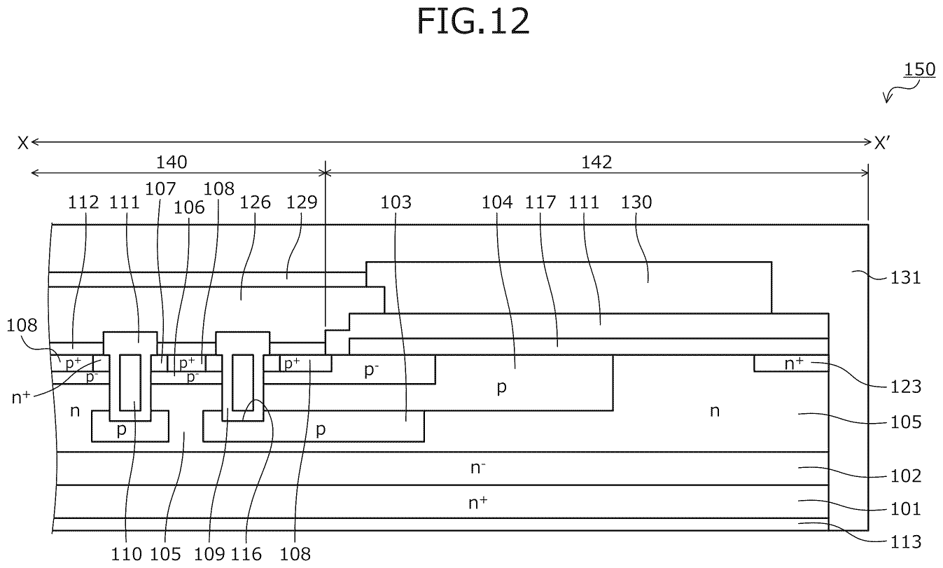

Here, findings underlying the present disclosure are discussed. First, problems associated with a semiconductor device of a comparison example are discussed. FIG. 12 is a cross-sectional view depicting a structure of a silicon carbide semiconductor device of the comparison example. In FIG. 12, a trench-type MOSFET 150 is depicted as the silicon carbide semiconductor device of the comparison example.

As depicted in FIG. 12, the trench-type MOSFET 150 has MOS gates with a general trench gate structure in an active region 140 of a semiconductor substrate (hereinafter, silicon carbide substrate) containing silicon carbide, the MOS gates being provided in the silicon carbide substrate, at a front surface thereof (surface having a later-described p⁻-type base layer 106). The silicon carbide substrate (semiconductor chip) is formed by sequentially growing silicon carbide layers on an n⁺-type starting substrate (hereinafter, n⁺-type silicon carbide substrate) 101 containing silicon carbide, the silicon carbide layers constituting an n⁻-type drift layer 102, an n-type high-concentration region 105, and the p⁻-type base layer 106. Hereinafter, the n⁺-type silicon carbide substrate 101, the n⁻-type drift layer 102, the n-type high-concentration region 105, and the p⁻-type base layer 106 collectively are assumed to be a silicon carbide semiconductor substrate.

At a front side of the n⁺-type silicon carbide substrate 101 (side having the n⁻-type drift layer 102), a MOS gate structure is provided, formed by the p⁻-type base layer 106, n⁺-type source regions 107, p⁺-type contact regions 108, trenches 116, gate insulating films 109, and gate electrodes 110. Further, reference numerals 111, 112, 126, and 129 are an interlayer insulating film, ohmic electrodes, a source electrode pad, and a plating film, respectively. A back electrode 113 constituting a drain electrode is provided at a back surface of the n⁺-type silicon carbide substrate 101. In the n-type high-concentration region 105, first p-type base regions 103 are selectively provided so as to entirely underlie bottom surfaces of the trenches 116.

Further, as depicted in FIG. 12, the trench-type MOSFET 150 includes the active region 140 through which current flows when a formed device structure is in an on-state, and a termination structure region 142 that surrounds a periphery of the active region 140 in a plan view and sustains a breakdown voltage.

In the silicon carbide semiconductor substrate, the first p-type base regions 103, a second p-type base region 104, and the p⁻-type base layer 106 are partially provided in the termination structure region 142 while in a region free of the second p-type base region 104 and the p⁻-type base layer 106, the n-type high-concentration region 105 is exposed and on the n-type high-concentration region 105, a voltage withstanding structure such as a guard ring structure or a JTE structure is provided.

In a guard ring structure, multiple p-type regions of differing dopant concentrations are disposed in substantially rectangular shapes surrounding the periphery of the active region 140 in a plan view, so that the p-type regions are disposed in descending order of dopant concentration in a direction from an inner side (side closer to a center of the n⁺-type silicon carbide substrate 101) to an outer side (side closer to a chip end of the n⁺-type silicon carbide substrate 101). Further, closer to the chip end than is the voltage withstanding structure, an n⁺-type region 123 constituting a channel stopper is disposed. At a surface of the voltage withstanding structure and a surface of the n⁺-type region 123, a field insulating film 117 and an interlayer insulating film 111 are provided and at a surface of the trench-type MOSFET 150, a polyimide film 130 is provided as a protective film.

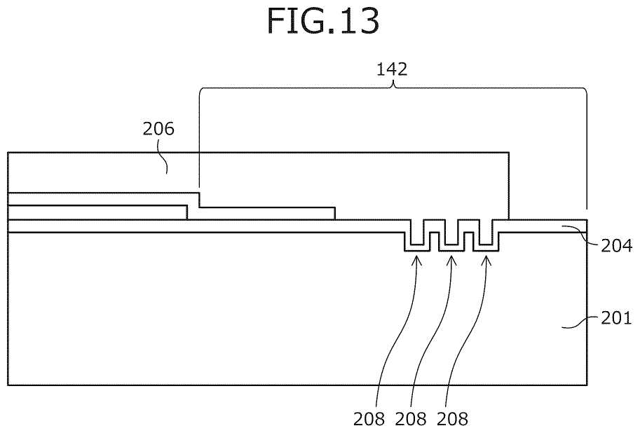

Further, FIG. 13 is a cross-sectional view depicting a structure having grooves at an end of the silicon carbide semiconductor device of the comparison example. FIG. 13 depicts the structure in Japanese Laid-Open Patent Publication No. 2023-172987 and in FIG. 13, in a semiconductor substrate 201, at a top surface thereof, protrusions having a tapered shape or grooves 208 having a concave shape are provided; an oxide film 204 is provided in the grooves 208; and the grooves 208 are embedded with an organic insulating film 206. Similarly, Japanese Laid-Open Patent Publication No. 2023-172987 describes an effect of improving adhesion to the organic insulating film 206 by an anchoring effect.

Conventionally, while gel encapsulation has been a primary chip encapsulation technique for semiconductor devices, encapsulation using a mold resin 131 is a technique for highly heat-resistant and highly reliable chip encapsulation for power semiconductors used in automobiles. As depicted in FIG. 12, a chip surface in direct contact with the mold resin 131 may be a surface of a plating film 129, the polyimide film 130, the interlayer insulating film 111, or the like and thus, the strength of adhesion to the mold resin 131 is different for each part.

Further, in an instance in which a thermal shock test is performed, peeling from the mold resin 131 occurs over a wide area of the chip. For example, peeling of the plating film 129, the polyimide film 130, the interlayer insulating film 111, or the like occurs. In particular, adhesion between the mold resin 131 and an oxide film (the interlayer insulating film 111) is low, the mold resin 131 begins peeling from an outermost periphery of the chip, and a state in which the peeling stops at a resin surface such as the polyimide film 130 may be observed. A problem arises in that, in the termination structure region 142, the polyimide film 130 cannot be formed to a scribe surface (chip end) and thus, the strength of adhesion of the exposed interlayer insulating film 111 has to be ensured.

With respect to the problem of the mold resin 131 peeling from the outermost periphery of the chip in the thermal shock test, a structure has been proposed in which unevenness is provided at a portion of the surface of the interlayer insulating film 111 not covered by the polyimide film 130.

In this structure, unevenness is formed in the interlayer insulating film 111 from the chip outer peripheral portion to a lower portion of the polyimide film 130; peeling of the mold resin 131 is prevented by the unevenness; and a further effect of preventing peeling with respect to the polyimide film 130 that is at a lower portion of the mold resin 131 is obtained. Furthermore, the interlayer insulating film 111 is etched thereby exposing the field insulating film 117 at bottoms of recesses, and an insulating film is formed to be continuous from the chip outer peripheral portion to the chip end. As a result, a notable point is that adhesion between the chip outer peripheral portion and the mold resin 131 does not significantly change.

Here, in a thermal shock test, an example of peeling of the encapsulation resin (the mold resin 131) in the chip end portion covered by the interlayer insulating film 111 was investigated. As a result, when examining where the mold resin 131 peeled, it was observed that while peeling occurred over a wide area of the chip, for example, at the plating film 129, the polyimide film 130, and the interlayer insulating film 111, silicon carbide exposed a surface of the n⁺-type silicon carbide substrate 101 and the mold resin 131 did not peel. This is presumed to be an anchoring effect of the mold resin 131 obtained by fine unevenness of the n⁺-type silicon carbide substrate 101 formed during dicing. In the present disclosure, with a focus on silicon carbide at the chip end surface, a structure that is relatively more resistant to peeling is proposed.

Embodiments of a semiconductor device according to the present disclosure, which solves the described problems associated with the described semiconductor device of the comparison example and the described method of manufacturing the semiconductor device, are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described. Further, with consideration of variation in manufacturing, description indicating the same or equal may be within 5%.

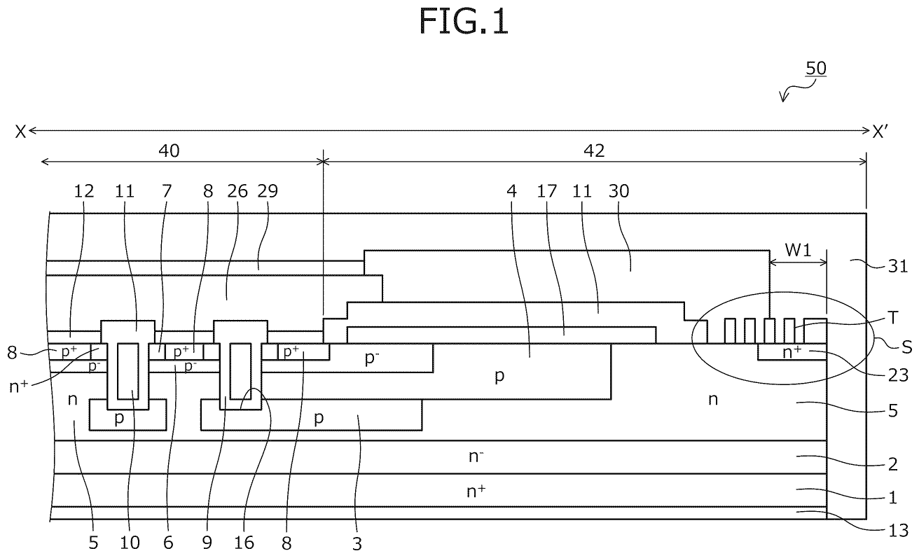

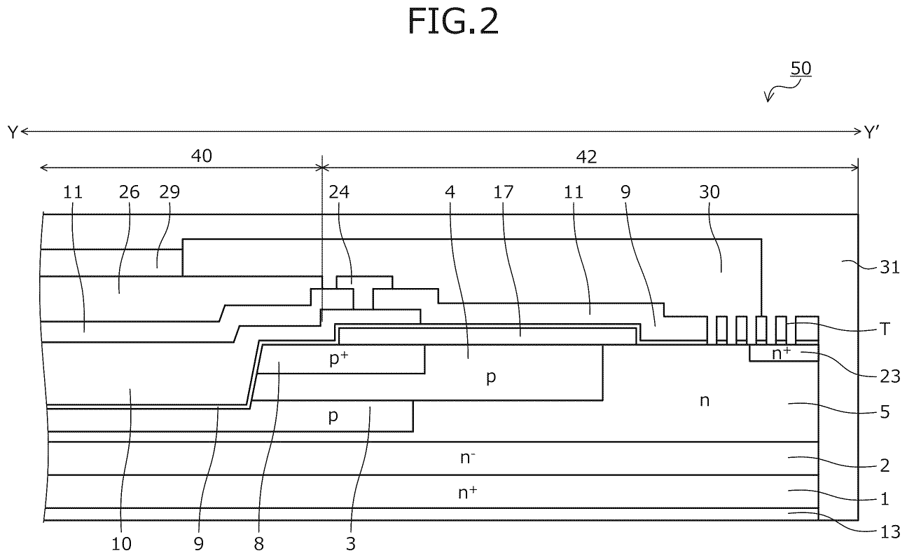

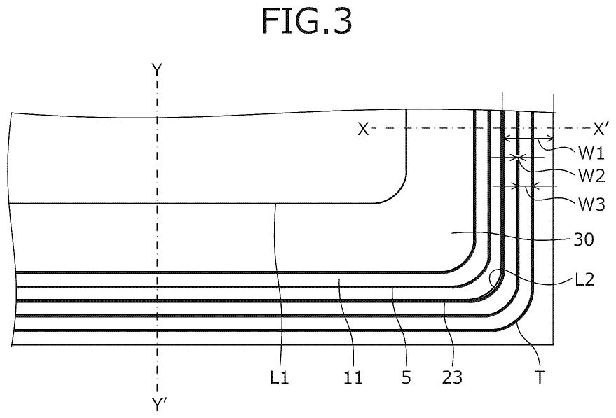

A semiconductor device according to the present disclosure contains a wide band gap semiconductor. In a first embodiment, a silicon carbide semiconductor device fabricated (manufactured) using, for example, silicon carbide (SiC) as a wide band gap semiconductor is described taking a trench-type MOSFET 50 as an example. FIG. 1 is a cross-sectional view depicting a structure of the silicon carbide semiconductor device according to the first embodiment, along cutting line X-X′ depicted in FIG. 3. FIG. 2 is a cross-sectional view depicting the structure of the silicon carbide semiconductor device according to the first embodiment, along cutting line Y-Y′ depicted in FIG. 3. FIG. 3 is a top view of the structure of the silicon carbide semiconductor device according to the first embodiment. FIG. 3 depicts a plan view of the structures of the top surface of a termination structure region 42, as viewed through a polyimide film 30.

As depicted in FIGS. 1 to 3, the trench-type MOSFET 50 according to the first embodiment includes an active region 40 in which device structures are formed and through which current flows in an on-state, and the termination structure region 42, which surrounds a periphery of the active region 40 in a plan view and sustains a breakdown voltage. Further, in the trench-type MOSFET 50, at a first main surface (front surface), for example, a (0001) plane (Si surface), of an n⁺-type silicon carbide substrate (semiconductor substrate of a first conductivity type) 1, an n-type drift layer (first semiconductor region of the first conductivity type) 2 is stacked.

The n⁺-type silicon carbide substrate 1 is a silicon carbide single crystal substrate. The n⁻-type drift layer 2 is, for example, a low-concentration n-type drift layer having a dopant concentration that is lower than is a dopant concentration of the n⁺-type silicon carbide substrate 1. At a first surface of the n⁻-type drift layer 2, opposite to a second surface thereof facing the n⁺-type silicon carbide substrate 1, an n-type high-concentration region 5 may be provided. The n-type high-concentration region 5 is a high-concentration n-type layer having a dopant concentration that is lower than the dopant concentration of the n⁺-type silicon carbide substrate 1 and higher than the dopant concentration of the n⁻-type drift layer 2.

At a first surface of the n-type drift layer 2 (when the n-type high-concentration region 5 is provided, at a first surface of the n-type high-concentration region 5, hereinafter, “(5)”), opposite to a second surface thereof facing the n⁺-type silicon carbide substrate 1, a p⁻-type base layer 6 is provided. Hereinafter, the n⁺-type silicon carbide substrate 1, the n-type drift layer 2, the n-type high-concentration region 5, and the p⁻-type base layer 6 are collectively regarded as a silicon carbide semiconductor substrate. In the p⁻-type base layer 6, n⁺-type source regions 7 are selectively provided. In the p⁻-type base layer 6, p⁺-type contact regions 8 are selectively provided.

At a second main surface (back surface, i.e., back surface of the silicon carbide semiconductor substrate) of the n⁺-type silicon carbide substrate 1, a drain electrode constituting a back electrode 13 is provided.

In the silicon carbide semiconductor substrate, the first main surface (surface having the p⁻-type base layer 6), a trench structure is formed. For example, trenches 16 penetrate through the p⁻-type base layer 6 from the first surface (the first main surface of silicon carbide semiconductor substrate) of the p⁻-type base layer 6 and reach the n-type drift layer 2 (5). Further, each of the trenches 16 has a linear shape. Along inner walls of the trenches 16, a gate insulating film 9 is formed at bottoms and sidewalls of the trenches 16, and on a front surface of the gate insulating film 9 in the trenches 16, gate electrodes 10 are formed. The gate insulating film 9 insulates the gate electrodes 10 from the n-type drift layer 2 (5) and the p⁻-type base layer 6. A portion of each of the gate electrodes 10 may protrude from a top (side facing later-described ohmic electrodes 12) of each of the trenches 16, in a direction toward the ohmic electrodes 12.

First p-type base regions 3 are provided at positions facing the bottoms of the trenches 16 in a depth direction, respectively. A width of each of the first p-type base regions 3 is wider than a width of each of the trenches 16. The bottoms of the trenches 16 may reach the first p-type base regions 3 or may be positioned in the n⁻-type drift layer 2 (5), between the p⁻-type base layer 6 and the first p-type base regions 3. The first p-type base regions 3 are doped with, for example, aluminum (Al).

Further, the trenches 16 of the active region 40 include outermost trenches that of the trenches 16 are closest to the termination structure region 42 and each of the outermost trenches has a sidewall facing the termination structure region 42, said sidewall being in contact with a second p-type base region 4 and the p⁻-type base layer 6 and being apart from (not in contact with) the n-type drift layer 2 (5).

An interlayer insulating film 11 is provided in an entire area of the front surface of the silicon carbide substrate, so as to cover the gate electrodes 10 embedded in the trenches 16. The interlayer insulating film 11 is formed by, for example, a high temperature oxide (HTO) and borophosphosilicate glass (BPSG). The ohmic electrodes (front electrodes) 12 are in ohmic contact with the n⁺-type source regions 7 and the p⁺-type contact regions 8 through contact holes opened in the interlayer insulating film 11. The ohmic electrodes 12 are electrically insulated from the gate electrodes 10 by the interlayer insulating film 11. On the ohmic electrodes 12, a source electrode pad 26 is provided. The ohmic electrodes 12 and the source electrode pad 26 may be a single layer or may be stacked layers of different materials. On the source electrode pad 26, a plating film 29 is provided. The plating film 29 is, for example, an Ni plating film or an Ni/Au plating film.

In FIG. 1, while two trench MOS structures are depicted in the active region 40, further trench MOS (insulated gates formed by metal-oxide-semiconductor) structures may be provided in parallel.

Further, as depicted in FIG. 2, in the termination structure region 42, a gate ring 24 for connecting the gate electrodes 10 to a gate electrode pad (not depicted) is formed. The gate ring 24 is formed, for example, in a substantially rectangular shape surrounding the periphery of the active region 40, in a plan view. In the termination structure region 42, a field insulating film 17 is provided on the second p-type base region 4 and the p⁻-type base layer 6 to insulate the second p-type base region 4 and the p-type base layer 6. On the field insulating film 17, the gate insulating film 9 and the interlayer insulating film 11 are provided. Further, in the termination structure region 42, a source ring (not depicted) for pulling out charge may be formed in a substantially rectangular shape surrounding a periphery of the gate ring 24, in a plan view.

Further, in a region of the termination structure region 42, free of the second p-type base region 4 and the p⁻-type base layer 6 and where the n⁻-type drift layer 2 is exposed, a voltage withstanding structure such as the guard ring structure (not depicted) or a junction termination extension (JTE) structure (not depicted) is provided on the n⁻-type drift layer 2.

The guard ring structure includes multiple dispersed p-type regions disposed in descending order of dopant concentration in a direction from the active region 40 to the chip end of the n⁺-type silicon carbide substrate 1, the p-type regions being disposed in substantially rectangular shapes surrounding the periphery of the active region 40, in a plan view. Further, instead of changing the dopant concentrations, the p-type regions may be disposed so that intervals therebetween are in ascending order or in descending order, in a direction from the chip center to the chip end. In an instance of a JTE structure, multiple connected p-type regions may be disposed in descending order of dopant concentration in a direction from the chip center (the active region 40) to the chip end (chip end side of the n⁺-type silicon carbide substrate 1), in substantially rectangular shapes surrounding the periphery of the active region 40, in a plan view. An n⁺-type region (second semiconductor region of the first conductivity type) 23 constituting a channel stopper is disposed closer to the chip than are these voltage withstanding structures. The channel stopper may be a p⁺-type region instead of the n⁺-type region 23. At the surfaces of the voltage withstanding structure and the n⁺-type region 23, the interlayer insulating film 11, the gate insulating film 9, and the field insulating film 17 are provided and the polyimide film 30 functioning as a protective film is provided at an uppermost surface of the trench-type MOSFET 50. Further, the trench-type MOSFET 50, exclusive of the back surface thereof, is encapsulated by a mold resin 31. The mold resin 31 is, for example, an epoxy resin. The back surface is bonded to a stacked substrate (not depicted) such as a ceramic substrate having at a front surface and a back surface thereof, conductive plates containing copper or the like, bonded by a bonding layer (not depicted) such as solder.

In the termination structure region 42, the polyimide film 30 cannot be formed to the scribe surface (chip end) and thus, the polyimide film 30 up to a midportion of the field insulating film 17, and in the chip end portion, the interlayer insulating film 11, which contains BPSG, are exposed. Here, the chip end is the scribe surface of the end of the semiconductor chip and the chip end portion is a region of the semiconductor chip where at least the n⁺-type region 23 is provided.

As depicted in FIGS. 1 to 3, in the first embodiment, in the chip end portion, the field insulating film 17 has a stacked structure including the interlayer insulating film 11 and the polyimide film 30, and is not provided at the chip end. Unevenness T is formed at the surface of the interlayer insulating film 11 (indicated by region S), from the n⁺-type region 23 to a region where the polyimide film 30 is formed. The unevenness T of the interlayer insulating film 11 is formed by grooves (trenches) that penetrate through the interlayer insulating film 11 and reach the SiC surface. Thus, at the unevenness T, SiC (the n⁻-type drift layer 2 (5), the n⁺-type region 23) is exposed and there are portions where the polyimide film 30 and the SiC are in contact with each other. Further, the tapered shape it makes it easier for the mold resin 31 and the polyimide film 30 to enter the groove.

In the first embodiment, the unevenness T is formed at the surface of the interlayer insulating film 11, from the n⁺-type region 23 to a region where the polyimide film 30 is formed, thereby forming an uneven pattern in the interlayer insulating film 11. The unevenness T is formed at the SiC surface, at a boundary L1 between the n-type drift layer 2 and the second p-type base region 4 or on the outer side of the JTE structure, in a plan view. In a region where the polyimide film 30 is formed, the polyimide film 30 is embedded in the grooves forming the unevenness T and outside the region where the polyimide film 30 is formed, the mold resin 31 is embedded in the grooves forming the unevenness T. Further, in the chip end portion, an exposed SiC portions is formed by dry etching and thus, surface roughness (Rmax: height difference of lowest valley and highest peak of surface) of the SiC at the unevenness T is in a range of about 3 nm to 10 nm and is greater than the roughness (Rmax) of 2 nm of a portion where the SiC surface is not etched.

For example, a width W1 of an opening of the polyimide film 30 between the end of the polyimide film 30 and the chip end portion is about 20 μm. The unevenness T is provided closer to the chip end than is the JTE portion or an outer peripheral ring, from the second p-type base region 4. In FIG. 3, the reference numeral L1 represents a boundary between the second p-type base region 4 and the n-type drift layer 2 at the SiC surface. A reference numeral L2 represents the boundary of the n⁺-type region 23 at the side thereof toward the active region 4. When a groove width W2 of the unevenness T become wider than 10 μm, the strength of adhesion tends to decrease and furthermore, a width of a gate contact opening of the gate ring 24 is 5 μm and the groove width W2 of the unevenness T also has to be an equivalent width. Therefore, preferably, the groove width W2 of the unevenness T may be in a range of 3 μm to 10 μm. Further, preferably, a groove interval (pitch) W3 between the grooves of the unevenness T may be about 15 μm.

As described, the field insulating film 17 in the chip end portion is removed; the unevenness T is formed in the interlayer insulating film 11; the SiC is exposed, and in the chip end portion, the interlayer insulating film 11 and exposed SiC portions are disposed alternating each other; and the uneven pattern is formed. As a result, the anchoring effect of the mold resin 31 is obtained by the fine unevenness of the SiC surface formed by etching and the uneven pattern of the interlayer insulating film 11, whereby the strength of adhesion between the chip and the mold resin 31 is improved and peeling of the mold resin 31 is prevented. Thus, the silicon carbide semiconductor device according to the first embodiment may improve reliability with respect to thermal shock. Further, even when the mold resin 31 peels, adhesion of the polyimide film 30 is improved and thus, peeling is further prevented.

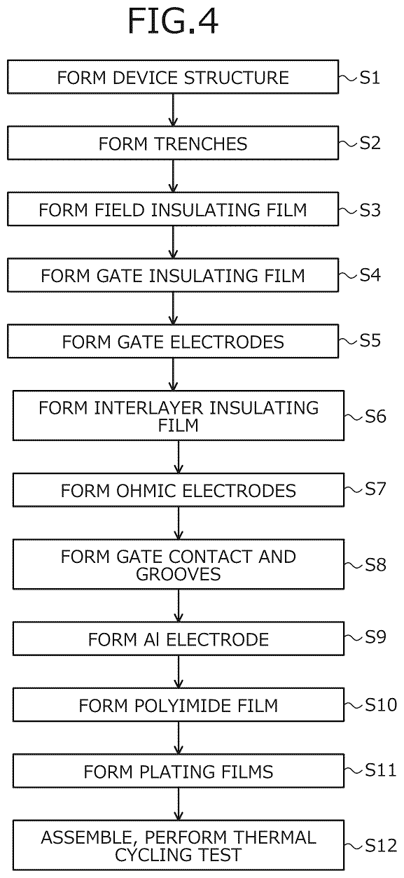

A method of manufacturing the silicon carbide semiconductor device according to the first embodiment is described. The method of manufacturing the silicon carbide semiconductor device according to the first embodiment may be as follows. FIG. 4 is a flowchart of the method of manufacturing the silicon carbide semiconductor device according to the first embodiment. Here, an instance in which a MOSFET of a 1200V breakdown voltage class is fabricated is described as an example. First, as described below, a device structure is formed (step S1: first process, second process). For example, the n⁺-type silicon carbide substrate (semiconductor wafer) 1 containing a silicon carbide single crystal and doped with an n-type impurity (dopant) such as nitrogen (N) so as to have a dopant concentration of 2.0×10¹⁹/cm³ is prepared. A front surface of the n⁺-type silicon carbide substrate 1, for example, may be a (0001) plane having an off angle of about 4 degrees in a <11-20> direction. Next, at the front surface of the n⁺-type silicon carbide substrate 1, for example, the n⁻-type drift layer 2 doped with an n-type impurity such as nitrogen so as to have a dopant concentration of 1.0×10¹⁶/cm³ is grown by epitaxy and has, for example, a thickness of 10 μm.

Next, by photolithography and ion implantation, the n-type high-concentration region 5 may be selectively formed in the n⁻-type drift layer 2, at the surface thereof. In the ion implantation, an n-type impurity (dopant) such as nitrogen may be implanted to have a concentration of, for example, 1×10¹⁷/cm³.

Next, by photolithography and ion implantation, the first p-type base regions 3, the second p-type base region 4, and the p⁻-type base layer 6 are selectively formed in the n-type drift layer 2 (5). In the ion implantation, for example, a p-type impurity (dopant) such as aluminum (Al) may be implanted.

By the processes up to here, the silicon carbide substrate is fabricated in which in the n⁺-type silicon carbide substrate 1, at the front surface thereof, the n⁻-type drift layer 2, the n-type high-concentration region 5, and the p⁻-type base layer 6 are sequentially stacked. Next, formation of an ion implantation mask by photolithography and etching, ion implantation using the ion implantation mask, and removal of the ion implantation mask are repeatedly performed as one set of processes, whereby the n⁺-type source regions 7 and the p⁺-type contact regions 8 are formed in the p⁻-type base layer 6, at the surface thereof. Preferably, the dopant concentration of the p⁺-type contact regions 8 may be 1.0×10²⁰/cm³ or higher.

Next, in the termination structure region 42, the guard ring structure is selectively formed by photolithography and ion implantation. Next, in the termination structure region 42, the n⁺-type region 23 is formed by photolithography and ion implantation.

Next, a heat treatment (annealing) is performed thereby activating, for example, the first p-type base regions 3, the second p-type base region 4, the p⁻-type base layer 6, the n⁺-type source regions 7, the p⁺-type contact regions 8, and the n⁺-type region 23. A temperature of the heat treatment may be, for example, about 1700 degrees C. A period of the heat treatment may be, for example, about 2 minutes. As described, the ion-implanted regions may be collectively activated by a single session of the heat treatment or the heat treatment may be performed to activate the ion-implanted regions each time ion implantation is performed.

Next, on the surface (i.e., surfaces of the n⁺-type source regions 7 and the p⁺-type contact regions 8) of the p⁻-type base layer 6, an oxide film is formed. The oxide film may be, for example, a thermal oxide film or a deposited film. A thickness of a portion of the oxide film in the active region 40 is thinner than a thickness of a portion of the oxide film formed on the outer peripheral side of the termination structure region 42.

Next, at the surface of the oxide film, a resist mask (not depicted) having predetermined openings is formed by photolithography. Next, openings are formed in the oxide film by dry etching using the resist mask as a mask. Next, the resist mask is removed and the trenches 16 that penetrate through the n⁺-type source regions 7 and the p⁻-type base layer 6 and reach the n-type drift layer 2 (5) are formed by anisotropic dry etching using the oxide film as a mask (step S2). The bottoms of the trenches 16 reach the first p-type base regions 3.

Next, with the oxide film as is, isotropic etching and sacrificial oxidation are performed. These processes remove damage of the trenches 16 and round the bottoms of the trenches 16. The sequence in which the isotropic etching and the sacrificial oxidation are performed may be interchanged. Further, either the isotropic etching or the sacrificial oxidation alone may be performed. Thereafter, the portion of the oxide film having a thinner thickness and used as a mask to form the trenches 16 is removed. At this time, the portion of the oxide film having a thinner thickness and the sacrificial oxide film may be removed concurrently. The oxide film has a portion where the thickness thereof is relatively thinner and a portion where the thickness thereof is relatively thicker and in the termination structure region 42 and thus, etching removing the relatively thinner portion of the oxide film is performed over the entire surface, leaving the relatively thicker portion of oxide film in the termination structure region 42. The sacrificial oxide film (not depicted) may be removed together with the relatively thinner portion of the oxide film. Further, the oxide film is removed by etching and thus, the oxide film may be left in the termination structure region 42. The portion (relatively thicker portion of the oxide film) of the oxide film left in the termination structure region 42 constitutes the field insulating film 17 (step S3). When the oxide film is removed by etching, the field insulating film 17 is formed so that the SiC surface at the chip end portion is exposed.

Next, the gate insulating film 9 is formed along the surfaces of the field insulating film 17, the n⁺-type source regions 7 and the p⁺-type contact regions 8 and along the bottoms and the sidewalls of the trenches 16 (step S4). The gate insulating film 9 may be formed by thermal oxidation of a temperature of about 1000 degrees C. under an oxygen atmosphere 1000. Further, the gate insulating film 9 may be formed by a deposition method by a chemical reaction such as high temperature oxidation (HTO). The chip end portion is free of the field insulating film 17 and thus, the gate insulating film 9 is not formed in the chip end portion and the surface of SiC remains exposed in the chip end portion.

Next, on the gate insulating film 9, a polycrystalline silicon layer doped with, for example, phosphorus (P) atoms is formed. The polycrystalline silicon layer is formed so as to be embedded in the trenches 16. The polycrystalline silicon layer is patterned and left in the trenches 16, whereby the gate electrodes 10 are formed (step S5). A portion of each of the gate electrodes 10 may protrude at upper portions (ends near the ohmic electrodes 12) of the trenches 16.

Next, for example, phosphosilicate glass (PSG) of a thickness of about 1 μm is deposited so as to cover the gate insulating film 9 and the gate electrodes 10, thereby forming the interlayer insulating film 11 (step S6: third process). The interlayer insulating film 11 and the gate insulating film 9 are patterned and selectively removed, thereby forming contact holes, and exposing the n⁺-type source regions 7 and the p⁺-type contact regions 8. Thereafter, a heat treatment (reflow) is performed, thereby planarizing the interlayer insulating film 11.

Next, a conductive film forming the ohmic electrodes 12 is formed in the contact holes and on the interlayer insulating film 11 (step S7). The conductive film is selectively removed and, for example, only portions thereof in the contact holes are left as the ohmic electrodes 12. The ohmic electrodes 12 are formed so as to be in ohmic contact with the p⁺-type contact regions 8 and the n⁺-type source regions 7.

Next, the interlayer insulating film 11 is patterned and selectively removed thereby, forming gate contacts for embedding the gate ring 24. At this time, the unevenness T is concurrently formed at the surface of the interlayer insulating film 11, from the n⁺-type region 23 to a region where the polyimide film 30 is formed, the unevenness T being formed by grooves that reach the n⁻-type drift layer 2 (step S8: fourth process).

Next, for example, an aluminum film having a thickness of, for example, about 5 μm is provided by a sputtering technique, so as to cover the ohmic electrodes 12 and the interlayer insulating film 11. Thereafter, the aluminum film is selectively removed so that a portion that is left covers the active region 40 of the entire device structure, whereby an Al electrode formed by the gate ring 24, the source ring, the source electrode pad 26, and the gate electrode pad is formed (step S9). Thereafter, a polyimide is applied as a surface passivation film by, for example, a spin coating technique, the polyimide is further patterned by a photolithographic technique, and cured by a heat treatment, thereby forming the polyimide film 30 (step S10: fifth process). The source electrode pad 26 may be a portion where the ohmic electrodes 12 are opened from the polyimide or may be formed by depositing another metal such as nickel in a portion where the ohmic electrodes 12 are opened from the polyimide.

Next, the surface of the Al film of the source electrode pad 26 is pretreated for plating in an etching bath or zincate treatment bath. Next, the plating film 29 is formed on the sputtered Al film by electroless Ni plating and Au plating (step S11).

Next, at the back surface (back surface of the n⁺-type silicon carbide substrate 1) of the silicon carbide substrate, the back electrode 13 constituted by, for example, a nickel (Ni) film is formed. Thereafter, for example, a heat treatment is performed at a temperature of about 970 degrees C., thereby forming an ohmic junction between the n⁺-type silicon carbide substrate 1 and the back electrode 13.

The back electrode 13 may be, for example, a stacked film in which titanium (Ti), nickel (Ni), and gold (Au) are sequentially stacked or a stacked film containing nickel (Ni), titanium (Ti), molybdenum (Mo), and gold (Au).

Thereafter, the semiconductor wafer is diced (cut) into individual semiconductor chips, the semiconductor chips are mounted to a stacked substrate by a bonding layer such as solder, and bonding of a lead frame and the semiconductor chips is performed. Thereafter, the stacked substrate is encapsulated by the mold resin 31, the semiconductor device is assembled and thereafter, a thermal cycling test is performed (step S12). As described above, the semiconductor device depicted in FIGS. 1 to 3 is completed. The thermal cycling test is a test that checks whether the mold resin 31 peels when, for example, thermal shock (−40 degrees C. for 5 minutes, 10 seconds later, 150 degrees C. for 5 minutes) is repeatedly performed 1000 times. The temperatures of the thermal cycling test are determined by usage conditions of the product.

As described, according to the first embodiment, unevenness is provided at the surface of interlayer insulating film so as to span from the n⁺-type region to a region where the polyimide film is formed, the SiC being exposed and thereby forming the uneven pattern. As a result, the anchoring effect of the mold resin is obtained by the fine unevenness of the SiC surface formed by etching and the uneven pattern of the interlayer insulating film. Thus, the strength of adhesion between the chip and the mold resin is improved, peeling of the mold resin may be prevented, and reliability with respect to thermal shock may be improved.

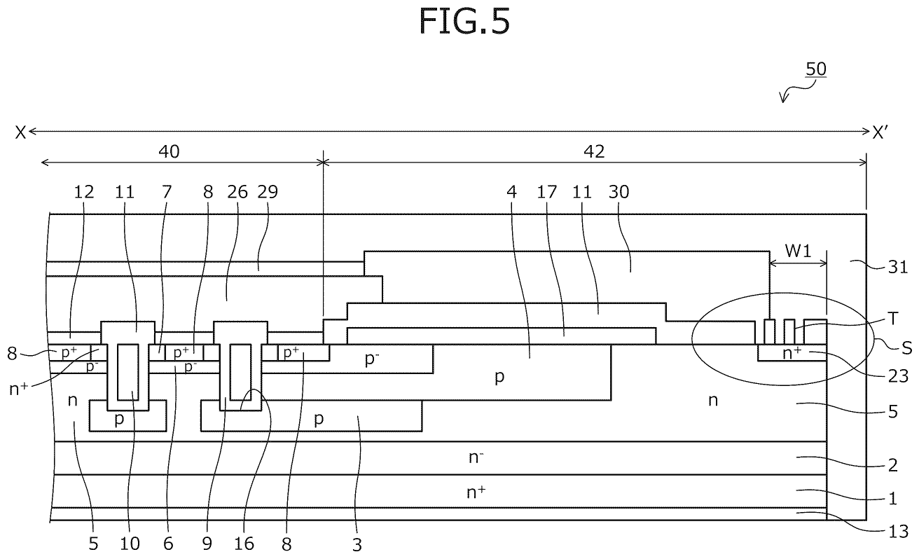

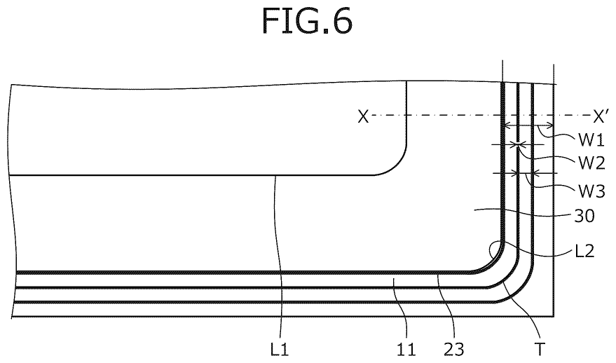

Next, a second embodiment is described. FIG. 5 is a cross-sectional view depicting a structure of a silicon carbide semiconductor device according to the second embodiment, along cutting line X-X′ depicted in FIG. 6. FIG. 6 is a top view of the structure of the silicon carbide semiconductor device according to the second embodiment. The second embodiment differs from the first embodiment in the location of the unevenness T of the region S. Other than the region S, configuration is the same as that of the first embodiment and thus, a cross-sectional view along cutting line Y-Y′ in the second embodiment is omitted.

In the second embodiment, from the outermost periphery of the polyimide film 30 and from the outer side thereof to the n⁺-type region 23, the unevenness T is provided at the surface of the interlayer insulating film 11 and reaches the SiC surface. The unevenness T overlaps the polyimide film 30 and has a single-groove structure.

In the second embodiment, for example, the width W1 of the opening of the polyimide film 30 between the end of the polyimide film 30 and the chip end portion is about 20 μm. In FIG. 6, the reference numeral L1 represents the boundary between the second p-type base region 4 and the n⁻-type drift layer 2 at the SiC surface. The reference numeral L2 represents a boundary of the n⁺-type region 23 toward the active region 40. Preferably, the groove width W2 of the unevenness T may be in a range of 3 μm to 10 μm, similar to the first embodiment. Further, preferably, the groove interval W3 (the pitch) between grooves of the unevenness T may be about 15 μm.

In the second embodiment as well, similar to the first embodiment, from the outermost periphery of the polyimide film 30 and from the outer side thereof to the n⁺-type region 23, the unevenness T is provided at the surface of the interlayer insulating film 11 and reaches the SiC surface. As a result, effects similar to those of the first embodiment are obtained.

Further, the silicon carbide semiconductor device according to the second embodiment may be manufactured by a same method as that of the first embodiment. For example, in the second embodiment, when the gate contact for embedding the gate ring 24 is formed, the unevenness T is formed from the outermost periphery of the polyimide film 30 and from the outer side thereof to the n⁺-type region 23, at the surface of the interlayer insulating film 11, by grooves that reach the n-type drift layer 2.

As described, according to the second embodiment, from the outermost periphery of the polyimide film and from the outer side thereof to the n⁺-type region, the uneven pattern is provided at the surface of the interlayer insulating film, exposing the SiC. As a result, the anchoring effect of the mold resin is obtained by the fine unevenness of the SiC surface formed by etching and the uneven pattern of the interlayer insulating film. Thus, the strength of adhesion between the chip and the mold resin is improved, peeling of the mold resin may be prevented, and reliability with respect to thermal shock may be improved.

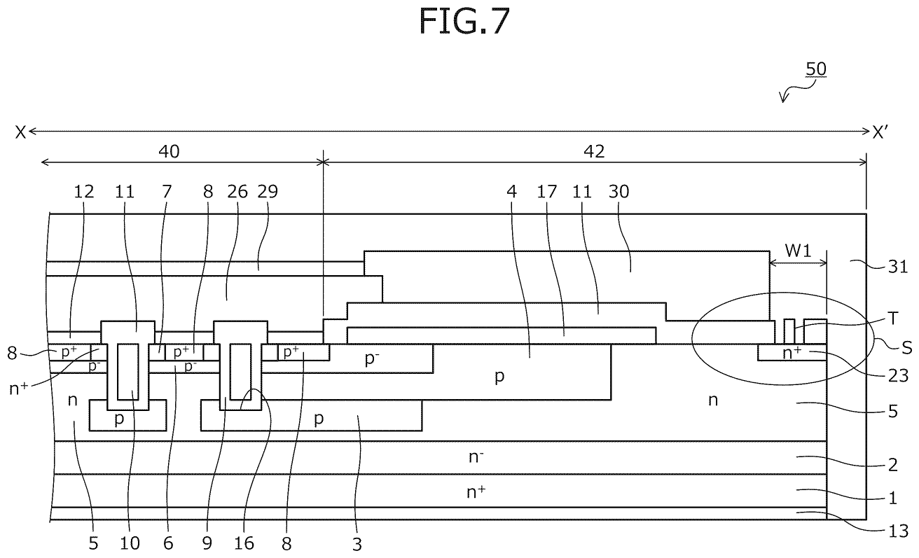

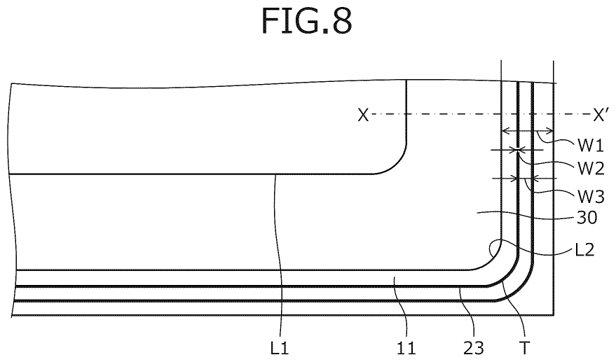

Next, a third embodiment is described. FIG. 7 is a cross-sectional view depicting a structure of a silicon carbide semiconductor device according to the third embodiment, along cutting line X-X′ depicted in FIG. 8. FIG. 8 is a top view of the structure of the silicon carbide semiconductor device according to the third embodiment. The third embodiment differs from the first embodiment in the location of the unevenness T of the region S. Other than the region S, configuration is the same as that of the first embodiment and thus, a cross-sectional view along cutting line Y-Y′ in the third embodiment is omitted.

In the third embodiment, the unevenness T is provided closer to the chip end than is the polyimide film 30, at the surface of the interlayer insulating film 11 above the n⁺-type region 23, and reaches the SiC surface. While the effect may be obtained with a single groove, multiple grooves provided closer to the chip end than is the polyimide film 30 is more effective. FIGS. 7 and 8 depict 2 grooves as an example.

In the third embodiment as well, for example, the width W1 of the opening of the polyimide film 30 between the end of the polyimide film 30 and the chip end portion is about 20 μm. In FIG. 8, the reference numeral L1 represents the boundary between the second p-type base region 4 and the n⁻-type drift layer 2 at the SiC surface. The reference numeral L2 represents a boundary of the n⁺-type region 23 toward the active region 40. Preferably, the groove width W2 of the unevenness T may be in a range of 3 μm to 10 μm, similar to the first embodiment. Further, preferably, the groove interval (the pitch) W3 between grooves of the unevenness T may be about 15 μm.

In the third embodiment as well, similar to the first embodiment, the unevenness T is provided closer to the chip end than is the polyimide film 30, at the surface of the interlayer insulating film 11 above the n⁺-type region 23. As a result, effects similar to those of the first embodiment are obtained.

Further, the silicon carbide semiconductor device according to the third embodiment may be manufactured by a same method as that of the first embodiment. For example, in the third embodiment, when the gate contact for embedding the gate ring 24 is formed, the unevenness T is formed closer to the chip end than is the polyimide film 30, at the surface of the interlayer insulating film 11, by grooves that reach the n⁻-type drift layer 2.

As described, according to the third embodiment, the unevenness is provided closer to the chip end than is the polyimide film, at the surface of the interlayer insulating film above the n⁺-type region, exposing the SiC, and forming the uneven pattern. As a result, the anchoring effect of the mold resin is obtained by the fine unevenness of the SiC surface formed by etching and the uneven pattern of the interlayer insulating film. Thus, the strength of adhesion between the chip and the mold resin is improved, peeling of the mold resin may be prevented, and reliability with respect to thermal shock may be improved.

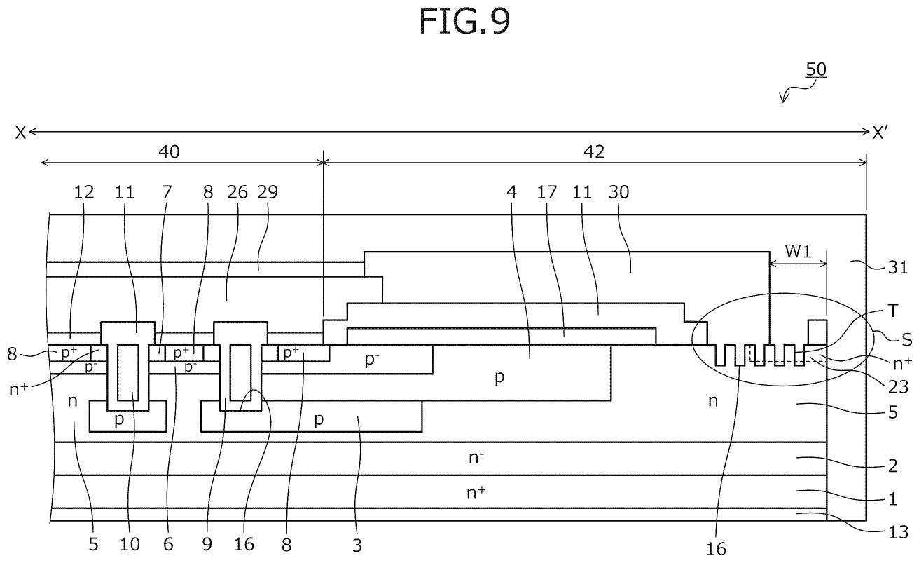

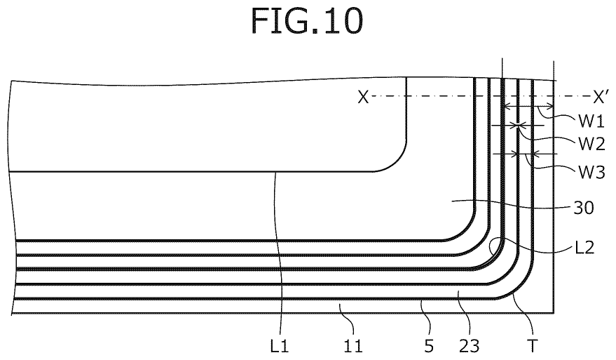

Next, a fourth embodiment is described. FIG. 9 is a cross-sectional view depicting a structure of a silicon carbide semiconductor device according to the fourth embodiment, along cutting line X-X′ depicted in FIG. 10. FIG. 10 is a top view of the structure of the silicon carbide semiconductor device according to the fourth embodiment. The fourth embodiment differs from the first embodiment in the location of the unevenness T of the region S. Other than the region S, configuration is the same as that of the first embodiment and thus, a cross-sectional view along cutting line Y-Y′ in the fourth embodiment is omitted.

In the fourth embodiment, in the chip end portion, the field insulating film 17 and the polyimide film 30 are removed, exposing the SiC (the n-type drift layer 2 (5) and the n⁺-type region 23), and the trenches 16 are formed at the SiC surface, whereby the unevenness T is provided. In FIG. 9, similar to the first embodiment, while the trenches 16 are provided at the surfaces of the n⁻-type drift layer 2 (5) and the n⁺-type region 23 from the n⁺-type region 23 to a region where the polyimide film 30 is formed, similar to the second embodiment, the trenches 16 may be provided at the surface of the n⁺-type region 23, from the outermost periphery of the polyimide film 30 and from the outer side thereof to the n⁺-type region 23. Furthermore, similar to the third embodiment, the trenches 16 may be provided at the surface of the n⁺-type region 23, closer to the chip end than is the polyimide film 30.

In the fourth embodiment as well, for example, the width W1 of the opening of the polyimide film 30, from the end of the polyimide film 30 to the chip end portion is about 20 μm. Preferably, the groove width W2 of each of the trenches 16 may be in a range of 0.3 μm to 3 μm. Further, preferably, the groove interval (the pitch) W3 between the trenches 16 may be about 15 μm.

In the fourth embodiment as well, similar to the first embodiment, the trenches 16 are provided at the surfaces of the n⁻-type drift layer 2 (5) and the n⁺-type region 23 from the n⁺-type region 23 to a region where the polyimide film 30 is formed. As a result, effects similar to those of the first embodiment are obtained.

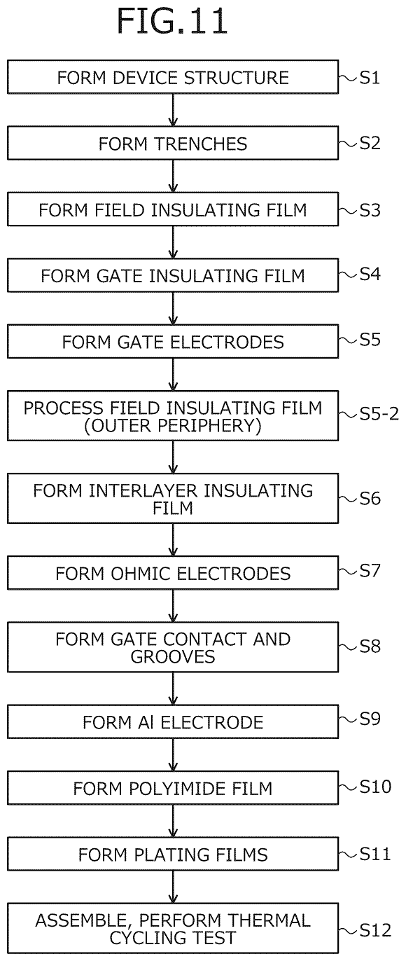

Further, the silicon carbide semiconductor device according to the fourth embodiment, may be manufactured by a same method as that of the first embodiment. FIG. 11 is a flowchart of a method of manufacturing the silicon carbide semiconductor device according to the fourth embodiment. In the fourth embodiment, when the trenches 16 are formed in the active region 40, the trenches 16 are formed in the n⁻-type drift layer 2, at the end thereof, whereby the unevenness T may be formed. For example, when the trenches 16 are formed, SiHₓF_{y}+SF₆+O₂+Ar may be used as an etching gas. However, when the oxide film is removed by the etching at step S3, a portion of oxide film at the chip end of the termination structure region 42 is also left, forming the field insulating film 17 so that the gate insulating film 9 and the gate electrodes 10 are not formed in the trenches 16 of the chip end portion. Thereafter, the gate electrodes 10 are formed and subsequently, the field insulating film 17 is etched so that the SiC surface is exposed in the chip end portion (step S5-2). When the trenches 16 are formed in the active region 40, the unevenness T is formed and thus, the depth of the trenches 16 and the depth of the unevenness T are about the same. When the trench width is 5 μm, differences in the area of mask openings cause a loading effect that changes the etching speed and shape, resulting in variations in trench depth. Thus, when the width of the trenches 16 is 0.5 μm, the groove interval of the unevenness T suffices to be in a range of 0.3 μm to 3 μm.

As described, according to the fourth embodiment, the unevenness is provided from the n⁺-type region to a region where the polyimide film is formed, exposing the n-type drift layer and the n⁺-type region, and forming trenches at the surfaces of the n⁻-type drift layer and the n⁺-type region. As a result, the anchoring effect of the mold resin is obtained by the fine unevenness of the SiC surface formed be etching and the uneven pattern of the interlayer insulating film. Thus, the strength of adhesion between the chip and the mold resin is improved, peeling of the mold resin may be prevented, and reliability with respect to thermal shock may be improved.

Table 1 depicts results of confirming whether peeling of the mold resin 31 when a thermal shock test is performed. The thermal shock test is a test performed to confirm whether peeling of the mold resin 31 occurred when thermal shock (−40 degrees C. for 5 minutes, 10 seconds later, 150 degrees C. for 5 minutes) was performed 1000 times.

TABLE 1

| | PEELING | LOCATION OF PEELING |
|---|---|---|
| COMPARISON | YES | FROM END OF CHIP TO |
| EXAMPLE | | END OF POLYIMIDE |
| FIRST | NO | |
| EMBODIMENT | | |
| SECOND | NO | |
| EMBODIMENT | | |
| THIRD | NO | |
| EMBODIMENT | | |
| FOURTH | NO | |
| EMBODIMENT | | |

As depicted in Table 1, while peeling of the mold resin 31 occurred from the chip end portion to the end of the polyimide in the silicon carbide semiconductor device depicted in FIG. 12 of the comparison example, in the first to fourth embodiments, peeling of the mold resin 31 did not occur. As a result, it was found that provision of the unevenness T at the surface of the interlayer insulating film 11 or the SiC surface may improve the strength of adhesion between the mold resin 31 and the SiC and may prevent peeling of the mold resin 31.

In the foregoing, while the present disclosure is described taking, as an example, an instance in which a MOS gate structure is provided in a silicon carbide, at the first main surface thereof, without limitation hereto, various modifications such as the orientation of the main surface of the substrate are possible. Further, in the embodiments of the present disclosure, while a trench-type MOSFET is described as an example, without limitation hereto, semiconductor devices of various configurations such as MOS-type semiconductor devices like trench-type IGBTs are applicable. Further, in the present disclosure, in the embodiments, while the first conductivity type is assumed to be an n-type and a second conductivity type is assumed to be a p-type, the present disclosure is similarly implemented when the first conductivity type is a p-type and the second conductivity type is an n-type.

According to the disclosure above, unevenness at the surface of the insulating film is provided from a second semiconductor region (the n⁺-type region) to a region where the polyimide film is formed, exposing the SiC and forming the uneven pattern. As a result, the anchoring effect of the mold resin is obtained by the fine unevenness of the SiC surface formed by etching and the uneven pattern of the interlayer insulating film. Thus, the strength of adhesion between the chip and the mold resin is improved, peeling of the mold resin may be prevented, and reliability with respect to thermal shock may be improved.

The semiconductor device and the method of manufacturing the semiconductor device according to the present disclosure achieve an effect in that reliability with respect to thermal shock may be improved when encapsulation by mold resin is used.

As described, the semiconductor device and the method of manufacturing the semiconductor device according to the present disclosure are useful for high voltage semiconductor devices used in power converting equipment, power supply devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a conductivity type, the semiconductor substrate having an active region and a termination region surrounding a periphery of the active region in a plan view;
a first semiconductor region of the conductivity type, provided on a surface of the semiconductor substrate;
a second semiconductor region of the conductivity type, provided in the first semiconductor region at a surface thereof, in an end portion of the termination region;
an insulating film provided at the surface of the first semiconductor region; and
a polyimide film selectively provided at a surface of the insulating film, wherein
the insulating film covers the surface of the first semiconductor region and a surface of the second semiconductor region,
the polyimide film covers the surface of the insulating film and reaches a portion of the end portion of the termination region, and
the semiconductor device further has, in the end portion of the termination region, an uneven portion through which the first semiconductor region and the second semiconductor region are exposed.

2. The semiconductor device, according to claim 1, wherein the uneven portion includes a groove, formed in the surface of the insulating film, that reaches the first semiconductor region and the second semiconductor region.

3. The semiconductor device, according to claim 2, wherein the uneven portion is positioned to partially overlap each of the second semiconductor region and the polyimide film in the plan view.

4. The semiconductor device, according to claim 2, wherein the uneven portion is positioned closer to the end portion of the termination region than is the polyimide film.

5. The semiconductor device, according to claim 1, wherein
the insulating film is provided partially in the end portion of the termination region, and
the uneven portion includes a groove provided at the surface of the first semiconductor region and the surface of the second semiconductor region.

6. The semiconductor device, according to claim 1, wherein surface roughness Rmax of the first semiconductor region and the second semiconductor region having the uneven portion is in a range of 3 nm to 10 nm.

7. The semiconductor device, according to claim 1, wherein the uneven portion includes a recess and a protrusion, a width of the protrusion being wider than a width of the recess.

8. A method of manufacturing a semiconductor device having an active region and a termination region surrounding a periphery of the active region in a plan view, the method comprising:
preparing a semiconductor substrate of a conductivity type;
forming a first semiconductor region of the conductivity type, on a surface of the semiconductor substrate;
forming a second semiconductor region of the conductivity type, in the first semiconductor region at a surface thereof, in an end portion of the termination region;
forming an insulating film at the surface of the first semiconductor region, the insulating film covering the surface of the first semiconductor region and a surface of the second semiconductor region;
forming an uneven portion exposing the first semiconductor region and the second semiconductor region, in the end portion of the termination region; and
forming a polyimide film at a surface of the insulating film, the polyimide film covering the surface of the insulating film and exposing at least the uneven portion.

9. A method of manufacturing a semiconductor device having an active region and a termination region surrounding a periphery of the active region in a plan view, the method comprising:
preparing a semiconductor substrate of a conductivity type;
forming a first semiconductor region of the conductivity type, on a surface of the semiconductor substrate;
forming a second semiconductor region of the conductivity type, in the first semiconductor region at a surface thereof, in an end portion of the termination region;
forming an insulating film at the surface of the first semiconductor region, the insulating film covering the surface of the first semiconductor region and a surface of the second semiconductor region;
forming an uneven portion having a groove, at the surface of the first semiconductor region and the surface of the second semiconductor region, in the end portion of the termination region; and
forming a polyimide film at a surface of the insulating film, the polyimide film covering the surface of the insulating film and exposing at least the uneven portion.
